(19) United States
(12) Patent Application Publication
(10) Pub. No.: US 2024/0219461 A2
(43) Pub. Date: Jul. 4, 2024

(54) CONTACTING MODULE HAVING A MOUNTING PLATE FOR CONTACTING OPTOELECTRONIC CHIPS

(71) Applicant: JENOPTIK Optical Systems GmbH, Jena (DE)

(72) Inventors: Robert BUETTNER, Jena (DE); Armin GRUNDMANN, Jena (DE); Tobias GNAUSCH, Jena (DE); Thomas KADEN, Dresden (DE); Stefan FRANZ, Jena (DE); Christian KARRAS, Jena (DE)

(21) Appl. No.: 18/041,598

(22) PCT Filed: Jan. 27, 2021
(86) PCT No.: PCT/DE2021/100078

§ 371 Date: Feb. 14, 2023

(30) Foreign Application Priority Data
Aug. 14, 2020 (DE) 10 2020 005 065.4

(51) Int. Cl. G01R 31/311; G01R 31/28

(52) U.S. Cl. CPC G01R 31/311; G01R 31/2887

(57) ABSTRACT

A contacting module and to a method for assembling a contacting module. The contacting module includes: an optical module which contains an optical block made of glass, which optical block has an arrangement of optical interfaces (Sₒₚₜ) in an optical interface plane (Eₒₚₜ); and an electronic module, which has an arrangement of electrical interfaces (Sₑₗₑ) in an electrical interface plane (Eₑₗₑ). The optical module and the electronic module are arranged relative to each other such that the arrangement of optical interfaces (Sₒₚₜ) and the arrangement of electrical interfaces (Sₑₗₑ) have a defined alignment position relative to each other. The optical module contains a mounting plate which is connected to the electronic module by means of a repeatedly releasable, reproducible connection.

### PRIORITY CLAIM

The present application is a National Phase entry of PCT Application No. PCT/DE2021/100078, filed Jan. 27, 2021, which claims priority from German Patent Application No. 10 2020 005 065.4, filed Aug. 14, 2020, the disclosures of which are hereby incorporated by reference herein in their entirety.

### FIELD OF THE INVENTION

The invention relates to a contacting module for testing optoelectronic chips.

### BACKGROUND OF THE INVENTION

The invention pertains to the field of testing and qualifying chips with opto-electrically integrated circuits, known as PICs (photonic integrated circuits), at wafer level. In contrast to conventional chips with purely electrically integrated circuits, so-called ICs (integrated circuits), PICs integrate optical functionalities as well as electric circuits.

In the manufacture of ICs, e.g. using CMOS technology, tests and measurements are carried out in various manufacturing steps in order to monitor the process on the one hand and to carry out quality control on the other. An established test is the electrical wafer level test after completion of the wafer. Here, functional and non-functional chips (known good dies) are identified and recorded in a wafer map, thereby determining the yield. When separating the wafer into individual chips, the non-functional chips are rejected. The test apparatus required for the wafer level test is available in the form of wafer probers and wafer testers with associated contacting modules (probe cards). The contacting module connects the interfaces (inputs and outputs) on the device side of the wafer tester with the individual interfaces (inputs and outputs) of the chips of the wafer fixed on the wafer prober. Typically, the contacting module is configured in such a way that it contacts only one chip, but it may also be configured to contact several chips at the same time. It is also not absolutely necessary that the chips for contacting are still present within the wafer composite. In order to contact several chips of a wafer simultaneously or one after the other, the chips merely need to have a fixed and defined position relative to each other. This margin is given for prior art contacting modules as well as for a contacting module according to the invention.

Test apparatuses for testing purely electronic chips (semiconductor chips with ICs) have been optimized and diversified over decades in order to be able to qualify high volumes of the most diverse ICs with high throughput for cost optimization.

PICs are usually manufactured using the same established semiconductor processes, e.g. CMOS technology. Initially, as a result of the very small production volumes of PICs compared to IC manufacture, only tests for process characterization, but no functional tests of the PICs, were usually carried out in a semiconductor factory. Functional characterization was the end customer's responsibility and was often performed on sawn chips. For the test apparatus used, independent, separate electrical and optical contacting modules were used.

Testing PICs at the wafer level requires the coupling and uncoupling of light from the PIC level, usually by means of integrated grating couplers as coupling points. Grating couplers can be functional components in the chip or sacrificial structures on the wafer, e.g. in the scribe lane or on adjacent chips.

The aforementioned US 2006/0109015 A1 discloses an optoelectronic contacting module (probe module) for testing chips with electrical and optical inputs and outputs (device under test—DUT), containing a contacting plate (probe substrate) and a redistribution plate (redistribution substrate). The contacting module constitutes an interface between a test apparatus (automated test equipment—ATE) and the DUT and is designed with electrical contacts (electrical probes), optical contacts (optical probes), optical elements and combinations thereof to conduct signals from the DUT and to the DUT and redistribute these signals for an interface to the test apparatus.

The separation into a contacting plate and a redistribution plate results in a modular design of the contacting module, which has the advantage that if the electrical contacts are damaged, the contacting plate can be replaced, while the redistribution plate can continue to be used with the comparatively expensive electrical and optical distribution network.

With regard to the optical inputs and outputs (optical interfaces), it is disclosed that these are created via optical elements located on the contacting plate and/or the redistribution plate and matched to various coupling mechanisms, e.g. free radiation, quasi-free radiation or waveguides. Suitable optical elements mentioned include diffractive elements and refractive elements. It is also stated that a photodetector or a light source may be located directly at the interface to the DUT and then constitute the optical input or output on the contacting plate.

According to an exemplary embodiment of the aforementioned US 2006/0109015 A1, the optical and electrical signal lines (optical and electrical distribution network) are embodied on separate redistribution plates. It is proposed to guide the electrical signals from the DUT to the edge regions of the contacting plate so that, in the first redistribution plate above the contacting plate, the electrical signals are coupled in above the edge region. This allows an opening to be formed in the first redistribution plate, in which only the electrical signals are redistributed, through which opening the optical signals are guided into a separate second redistribution plate above the first redistribution plate.

In summary, the aforementioned US 2006/0109015 A1 presents a multitude of ideas on how a contacting module, which is divided into a contacting plate and a redistribution plate for a reason, e.g. due to wear of the mechanical contacts for electrical signal transmission, could be additionally equipped with optical signal lines. This ignores the fact that the tolerances possible for the mechanical contact of the electrical inputs and outputs of the contacting module to the DUT cannot be transferred to the optical inputs and outputs.

While the transmission of a constant electrical signal via electrical interfaces requires the mechanical contact of needles present on the contacting module with contact plates (contact pads) present on the DUT, which can be ensured within a comparatively large position tolerance of a few μm in all three spatial directions, the quality of the optical signal transmission is already influenced by a much smaller deviation, in the submicron range, from its target position.

A contacting module that is insensitive to position tolerances of the optical interfaces is known from WO 2019/029765 A1. Similar to a contacting module according to the invention and to contacting modules known from the prior art, a contacting module as described therein is arranged between a wafer platform, e.g. a wafer prober, on which a wafer with optoelectronic chips under test is fixed, and a test apparatus for generating and evaluating optical signals and electrical signals. The contacting module establishes the signal-related connection between the individual optical and electrical interfaces of an optoelectronic chip under test and the specified device-related optical and electrical interfaces of the test apparatus. The interfaces are, respectively, electrical or optical inputs and outputs from or to which the electrical or optical signals are input or output, respectively, and are respectively transmitted to or from the optoelectronic chip under test, via electrical or optical signal lines.

The electrical interfaces on the contacting module 1 are each formed by the tips of contacting needles which, for transmitting the electrical signals, are each in mechanical contact with one electrical interface of the optoelectronic chip under test, each of which are formed by an electrical contact pad. As explained in detail in the description of the prior art, the tolerance limits required for reliable electrical contacting are large compared to the tolerances required for optical contacting.

It is also known from the aforementioned WO 2019/029765 A1 that the contacting module includes an electronic module on which the electrical interfaces are arranged and an optical module on which the optical interfaces are arranged. The optical module is attached to the electronic module in a defined manner via mechanical interfaces, whereby the arrangement of electrical interfaces has a defined relative position to the arrangement of optical interfaces.

The advantage compared to a monolithic contacting module is in particular that the electrical signal lines and the optical signal lines can be manufactured independently of each other by different manufacturing processes and also in or on substrates made of different materials. To ensure that all interfaces, whether optical or electrical, form a common arrangement that can be adjusted relative to the optoelectronic chip under test, the optical block is fixed in a manner adjusted to the electronic block.

In an advantageous embodiment of the contacting module, the optical block is advantageously embodied in its dimension and geometry, including breakthroughs and/or openings, in such a way that all contacting needles present on the electronic module can be in contact with the chip 2 past the optical block, around it and/or if necessary through openings formed therein. This enables the integration of all optical interfaces in one monolithic optical block.

In one embodiment example of a contacting module described in the aforementioned WO 2019/029765 A1, the electronic module corresponds in its technical design to a conventional contacting module for purely electronic chips. It contains a printed circuit board, an arrangement of contacting needles, embodied here, by way of example, as cantilever needles, and a carrier plate on which the mechanical interfaces to the test apparatus are located. The electrical contact is established via the electronic module by physical contact of the contacting needles with the electrical contact pads of the chip.

The optical module consists of an optical block with optical signal lines, each in the form of waveguides and an integrated mirror arranged in front of each waveguide, a fiber holder with V-grooves, as well as glass fibers and single fiber connectors or a multi-fiber connector. The waveguides are manufactured by a direct laser writing process and the mirrors are manufactured by a laser assisted etching process. Consequently, the waveguides are formed as a result of the input of laser energy by localized modified substrate material, which is characterized in particular by a local refractive index modification compared to the refractive index of the substrate material. The mirrors are formed by interfaces of etched recesses in the substrate material. The substrate material of the optical block is glass, preferably borofloat glass, and has a thickness in the range of several 100 μm to several millimeters, preferably 0.5-1 mm. The optical contacting takes place without direct contact with the chip over a distance between the chip and the contacting module. The process used to manufacture the mirrors and the waveguides enables the optical interfaces in particular to be manufactured with high precision relative to each other and to a mechanical interface on the optical block. Furthermore, free positioning of the mirrors and the waveguides within the substrate material is possible.

Preferably, the optical module is connected to the electronic module by being glued to a carrier plate in the electronic module, e.g. via three fixing points. When manufacturing the electronic module, e.g. with cantilever needles as the contacting needles, the Z-height of the needles is usually referenced to the clamping points of contacting module with a fixed reference to the wafer platform. With a metal frame as the carrier plate, these reference points are located on the metal frame into which the fixing points for the optical module are integrated with high precision. Thus, the optical module can be mounted exactly plane-parallel and precisely in relation to the reference plane of the tips of the contacting needles by positionally accurate gluing to the fixing points in the Z-direction. Plane-parallel mounting of the optical module on the electronic module also prevents the optical module from colliding with the chip in operation, during contacting, due to the small working distance. As an alternative to being fixed to the carrier plate, the optical block can also be attached directly to the printed circuit board.

A permanent fixed connection of the optical module to the electronic module, e.g. by gluing, has proven to be disadvantageous for various reasons. In the technological sequence of the individual process steps in the manufacture of the contacting module, it is advantageous in practice, e.g. when using vertical probe cards, to grind the tips of the contacting needles, which lie together in one plane to form the electrical interfaces of the contacting module to the optoelectronic chip under test, down to a predetermined working distance from the optical interfaces of the contacting module in a final process step. To know the reference plane for this, the optical module is mounted beforehand and the position of the plane described by the optical interfaces, which represents the reference plane, is determined. However, grinding off the tips of the contacting needles exposes the optical module, especially the optical block made of glass, to the risk of damage and soiling. The same applies if, for example, the contacting needles have to be replaced or cleaned during service or repair.

### SUMMARY OF THE INVENTION

It is an object of the invention to provide a contacting module in which the optical module is repeatedly detachably connected to the electronic module, thereby ensuring repeated, highly accurate production of the adjustment position of the arrangement of the optical interfaces to the arrangement of the electrical interfaces.

It is also an object of the invention to provide a suitable method for repeated high-precision assembly of a contacting module.

With respect to a contacting module, the object is achieved by a contacting module with an optical module, containing an optical block made of glass, with optical signal lines in the form of waveguides, with a mirror arranged in front of each waveguide, and with an arrangement of optical interfaces in an optical interface plane, and an electronic module, containing a carrier plate, a printed circuit board and a needle carrier with an arrangement of contacting needles with needle tips, which form an arrangement of electrical interfaces in an electrical interface plane, the optical module and the electronic module being arranged relative to one another in such a way that the arrangement of optical interfaces and the arrangement of electrical interfaces have a defined adjustment position relative to one another with respect to all six degrees of freedom of a Cartesian coordinate system, wherein the optical module contains a mounting plate to which the optical block is cohesively connected, and the mounting plate is connected to the carrier plate of the electronic module via a repeatedly detachable connection, said detachable connection ensuring repeated production of the adjustment position of the arrangement of the optical interfaces to the arrangement of the electrical interfaces.

Advantageous embodiments are provided in subclaims 2 to 6 which include backreferences.

With respect to a method, the object is achieved by a method for mounting a contacting module with an optical module, containing an optical block made of glass, which has an arrangement of optical interfaces in an optical interface plane and is mounted on a mounting plate, and an electronic module, containing a carrier plate, a printed circuit board and an arrangement of contacting needles with needle tips, which form an arrangement of electrical interfaces in an electrical interface plane, the optical module and the electronic module being arranged relative to one another in such a way that the arrangement of optical interfaces and the arrangement of electrical interfaces have a defined adjustment position relative to one another, in that before the optical block is fastened to the mounting plate, the mounting plate is connected to the carrier plate by means of a detachable connection in a relative position which can be produced repeatedly, the optical block is then adjusted relative to the mounting plate until the arrangement of the optical interfaces has assumed a predetermined adjustment position relative to the arrangement of the electrical interfaces, and finally the optical block is permanently connected to the mounting plate, whereby after each re-establishment of the detachable connection the arrangement of the optical interfaces is arranged in the predetermined adjustment position relative to the arrangement of the electrical interfaces.

An advantageous embodiment of the method is indicated in subclaim 8 which includes a backreference.

### BRIEF DESCRIPTION OF THE DRAWINGS

The invention will be explained in more detail below with reference to exemplary embodiments and drawings. In the drawings:

FIGS. 1a and 1b show a simplified representation of a contacting module in a top view and a lateral view,

FIGS. 2a and 2b show a first embodiment example of a contacting module having a first detachable connection between the optical module and the electronic module, in a top view and a lateral view,

FIGS. 3a and 3b show a second embodiment example of a contacting module having a second detachable connection between the optical module and the electronic module, in a top view and a sectional view,

FIGS. 4a and 4b show an adhesive connection between the optical block and the mounting plate of the optical module, in a top view and a sectional view,

FIG. 5a shows a first embodiment of the adhesive connection, and

FIG. 5b shows a second embodiment of the adhesive connection.

### DETAILED DESCRIPTION OF THE DRAWINGS

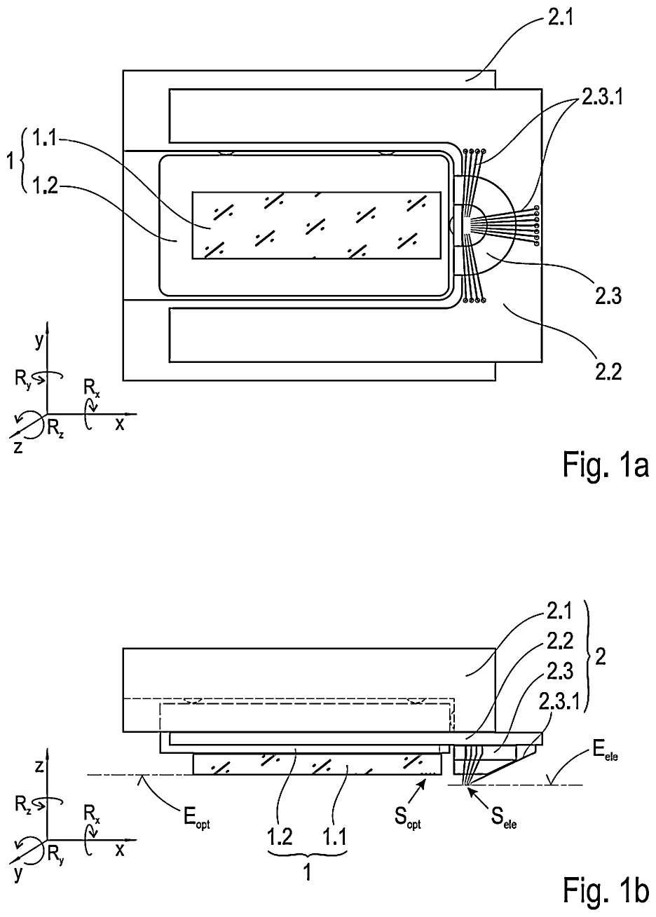

A contacting module according to the invention, as shown in FIGS. 1a and 1b, has an optical module 1 and an electronic module 2 like prior art contacting modules of the same generic type.

The optical module 1 includes an optical block 1.1 made of glass, which has an arrangement of optical interfaces Sₒₚₜ in an optical interface plane Eₒₚₜ which are arranged facing an optoelectronic chip under test. In addition, the optical module 1 has means for inputting and outputting optical signals into and out of the optical block 1.1, e.g., a fiber array, which are associated with a test device, which is important for the function but not essential for the explanation of the invention (not shown). It is also not essential for the invention how the optical interfaces Sₒₚₜ are designed.

The electronic module 2 contains a carrier plate 2.1, a printed circuit board 2.2 and a needle carrier 2.3 with an arrangement of contacting needles 2.3.1, in particular vertical needles or cantilever needles. The contacting needles 2.3.1 form an arrangement of electrical interfaces Sₑₗₑ with their needle tips in an electrical interface plane Eₑₗₑ. The carrier plate 2.1 and the needle carrier 2.3 are firmly connected to each other or form a monolithic unit.

The optical module 1 and the electronic module 2 are arranged relative to one another in such a way that the arrangement of optical interfaces Sₒₚₜ and the arrangement of electrical interfaces Sₑₗₑ have a defined adjustment position relative to one another with respect to all six degrees of freedom of a Cartesian coordinate system.

It is essential to the invention that the optical module 1 contains a mounting plate 1.2 to which the optical block 1.1 is cohesively connected by an adhesive connection. Via this mounting plate 1.2, the optical module 1 is connected to the electronic module 2, preferably to the carrier plate 2.1, by means of a detachable connection, said detachable connection ensuring repeated production of the adjustment position of the arrangement of the optical interfaces Sₒₚₜ to the arrangement of the electrical interfaces Sₑₗₑ. This adjustment position reflects the relative position of the arrangement of optical interfaces Sₒₚₜ and electrical interfaces Sₑₗₑ of an optoelectronic chip under test. The possibility of temporarily separating the optical module 1 and the electronic module 2 makes it possible to replace or clean, e.g. in the course of service or repair, the contacting needles 2.3.1 without the risk of soiling or damaging the optical block 1.1 made of glass.

The optical module 1 can be connected to the carrier plate 2.1 directly via the mounting plate 1.2 or indirectly, e.g. via the needle carrier 2.3. The direct connection has the advantage of a shorter tolerance chain.

Two advantageous embodiments for the detachable connection are shown below on the basis of embodiment examples. Also disclosed is a particularly advantageous way of providing the cohesive connection between the optical block 1.1 and the mounting plate 1.2.

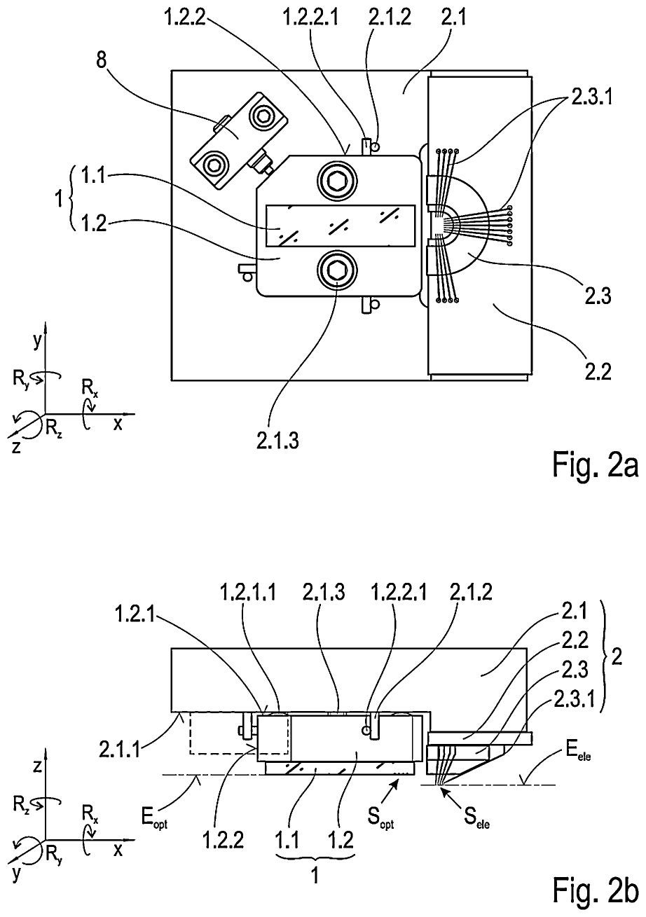

In a first embodiment example, shown in FIGS. 2a and 2b, on a first end face 1.2.1 of the mounting plate 1.2, three elevations 1.2.1.1 defining a mounting plane are present, which form a three-point support and which, by resting against a mounting surface 2.1.1 of the carrier plate 2.1, define the relative position of the mounting plate 1.2 in a z-direction about an x-direction and about a y-direction, i.e. in a rotational position Rx and in a rotational position Ry, of a Cartesian coordinate system with respect to the carrier plate 2.1. Three stop pins 1.2.2.1 aligned parallel to the mounting plane are provided on a circumferential surface of the mounting plate 1.2, against each of which a dowel pin 2.1.2 provided on the carrier plate 2.1 rests, so that the relative position of the mounting plate 1.2 in the x-direction, in the y-direction and about the z-direction, i.e. in a rotational position Rz, with respect to the carrier plate 2.1 is fixed. In the first embodiment example specifically shown, two of the three dowel pins 2.1.2 are arranged on an imaginary straight line oriented in the x-direction. Two of the stop pins 1.2.2.1 are aligned with each other in the x-direction and rest against the two dowel pins 2.1.2, and a third of the stop pins 1.2.2.1 is aligned in the y-direction and rests against the third of the dowel pins 2.1.2. Even if the mounting plate 1.2 is repeatedly removed from and mounted on the carrier plate 2.1, the mounting plate 1.2 assumes the same relative position to the carrier plate 2.1 in a tolerance-free manner. To place the stop pins 1.2.2.1 against the dowel pins 2.1.2, a contact pressure unit 8 can be temporarily placed on the carrier plate 2.1, for example. To fix the relative position, the mounting plate 1.2 is connected to the carrier plate 2.1 via at least one screw connection 2.1.3.

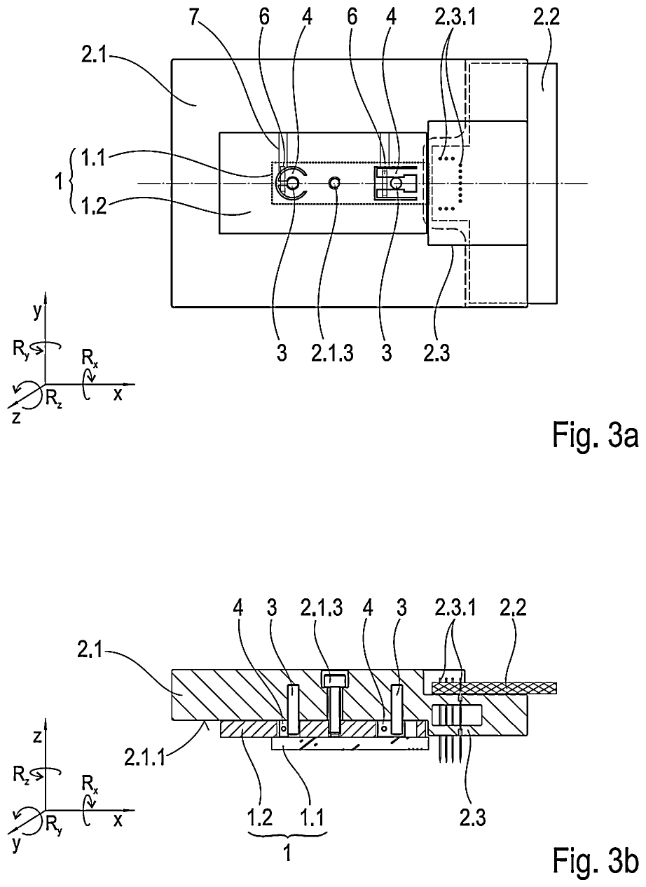

In a second embodiment example, shown in FIGS. 3a and 3b, the relative position of the mounting plate 1.2 in the x-direction, in the y-direction and about the z-direction to the carrier plate 2.1 is determined by a three-point support, analogous to the first embodiment example. The mounting plate 1.2 has two bending structures 4 penetrating the mounting plate 1.2 and formed, for example, by electroerosion. Two clamping pins 3 are provided on the carrier plate 2.1, aligned perpendicular to the mounting surface 2.1.1 and firmly connected to the carrier plate 2.1. They can be connected to the carrier plate 2.1 directly or indirectly, e.g. at the needle carrier 2.3, which is advantageously made of ceramic. For a detachable connection of the mounting plate 1.2 to the carrier plate 2.1, the two clamping pins 3 are each clamped in one of the bending structures 4. In the first of the two bending structures 4, the first of the two clamping pins 3 is clamped circumferentially via its lateral surface, thus fixing the relative position of the mounting plate 1.2 in the x-direction and the y-direction to the carrier plate 2.1. Advantageously, the first of the two bending structures 4 has the shape of a pipe clamp. In the second of the two bending structures 4, the second of the two clamping pins 3 is clamped tangentially via its lateral surface, thus fixing the relative position of the mounting plate 1.2 around the z-direction to the carrier plate 2.1.

To clamp the bending structures 4 on one of the clamping pins 3 in each case, the latter can be dimensioned in such a way that, in the stress-free state, they have an opening that is smaller than the cross-section of the clamping pins 3, so that they are clamped before or with the insertion of the clamping pins 3 and clamp the clamping pin 3.

Advantageously, the bending structures 4 are dimensioned so that they each have an opening that is larger than the cross-section of the clamping pins 3. Only after the clamping pins 3 have been inserted are the bending structures 4 tensioned to clamp the clamping pins 3. This can advantageously be done via a set screw 6, as shown.

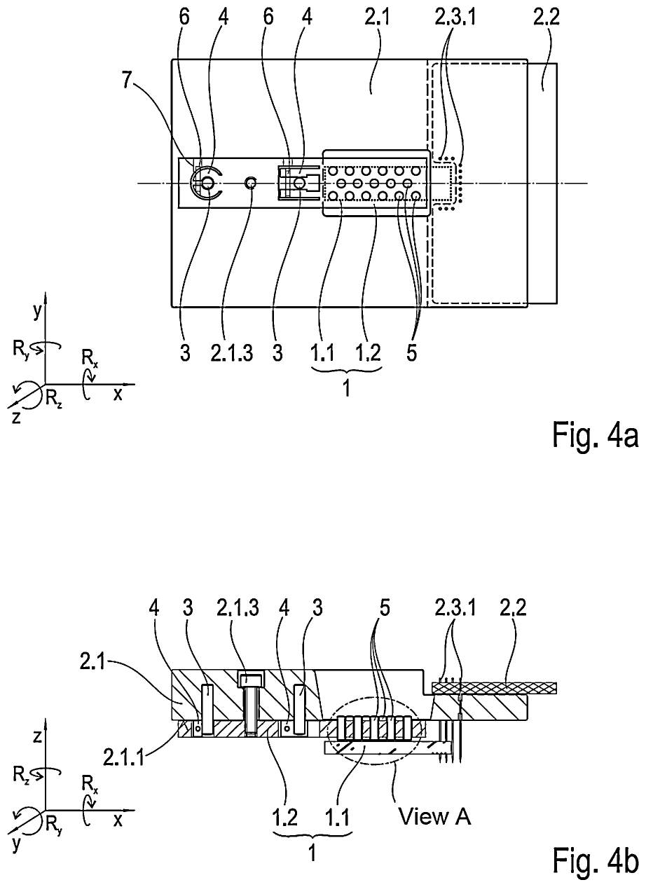

The optical block 1.1 made of glass is glued to the mounting plate 1.2. Advantageously, the adhesive connection between the optical block 1.1 and the mounting plate 1.2, as shown in FIGS. 4a and 4b, is an indirect adhesive connection via cylindrical pins 5 which are glued on the one hand to the optical block 1.1 and on the other hand to the mounting plate 1.2 and thus permanently connected. There are at least three cylindrical pins 5. They each contact the optical block 1.1 with a first end face 5.1 via adhesive. In the mounting plate 1.2, there is a corresponding number of through holes 7, in which the cylindrical pins 5 are each connected to the mounting plate 1.2 via adhesive 9. This type of connection has a particular advantage during assembly. The optical block 1.1 can be adjusted in all six degrees of freedom and glued to the mounting plate 1.2 in the adjustment position without adhesive 9 already being present on the optical block 1.1 or the mounting plate 1.2 during adjustment.

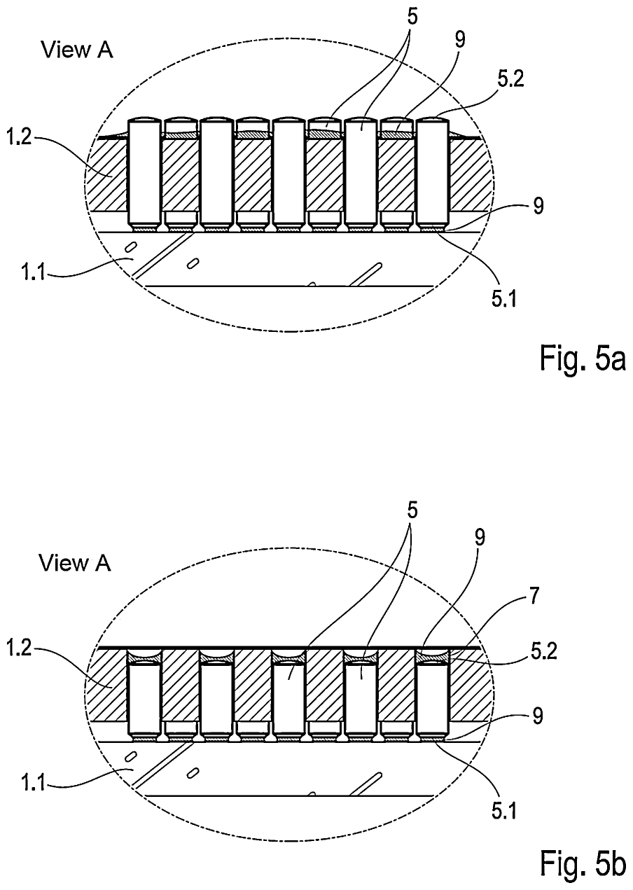

The connection of the cylindrical pins 5 in the through holes 7 can advantageously be established by the cylindrical pins 5 projecting beyond the mounting plate 1.2 and being enclosed by adhesive 9, as shown in FIG. 5a. Even more advantageously, the cylindrical pins 5 are dimensioned in such a way that a free volume remains above their second end face 5.2 in the through hole 7, which is filled with adhesive 9, as shown in FIG. 5b.

A method according to the invention for assembling a contacting module according to the invention will be explained in more detail below. As in the prior art, at the end of the adjustment and assembly, the optical module 1 and the electronic module 2 are arranged relative to one another in such a way that the arrangement of optical interfaces Sₒₚₜ and the arrangement of electrical interfaces Sₑₗₑ have a defined adjustment position relative to one another in all six degrees of freedom.

In contrast to the prior art, assembly according to the invention takes place in two steps.

Before the optical block 1.1 is attached to the mounting plate 1.2, the latter is connected to the carrier plate 2.1 via a repeatedly detachable connection, with the mounting plate 1.2 assuming a reproducible relative position to the carrier plate 2.1. No adjustment is made here, since what is important is not a defined relative position but a reproducible relative position which the mounting plate 1.2 assumes exactly again in relation to the carrier plate 2.1 each time the connection is re-established. This established connection can be secured by an additional screw connection 2.1.3.

After this detachable connection has been made for the first time, the optical block 1.1 is aligned and adjusted with respect to the mounting plate 1.2 until the arrangement of the optical interfaces Sₒₚₜ has assumed a predetermined adjustment position with respect to the arrangement of the electrical interfaces Sₑₗₑ. Only then is the optical block 1.1 permanently connected to the mounting plate 1.2 without their adjustment position to each other being cancelled. After each re-establishment of the detachable connection, the arrangement of the optical interfaces Sₒₚₜ will thus be arranged in the predetermined adjustment position with respect to the arrangement of the electrical interfaces Sₑₗₑ.

Advantageously, the permanent connection of the optical block 1.1 to the mounting plate 1.2 is established by making at least three through holes 7 in the mounting plate 1.2 parallel to each other, through which at least three cylindrical pins 5 are guided from a first end face of the mounting plate 1.2 facing away from the optical block 1.1, until they each come into contact with the adjusted optical block 1.1. Beforehand, adhesive 9 was applied to at least one end face of the cylindrical pins 5 facing the optical block 1.1 in each case. The adhesive 9 joining the cylindrical pins 5 to the mounting plate 1.2 can either also be applied to the circumferential surface of the cylindrical pins 5 prior to insertion of the cylindrical pins 5 into the through holes 7 or dispensed into the through holes 7. Advantageously, it can also be dispensed after the cylindrical pins 5 have been inserted and placed in the through holes 7, which are dimensioned for such a procedure such that the end faces of the cylindrical pins 5 facing away from the optical block 1.1 lie below a surface of the mounting plate 1.2, whereby the adhesive 9 fills a volume with a diameter of the through holes 7.

A defined adhesive surface for the cylindrical pins 5 is obtained by advantageously dimensioning the cylindrical pins 5 and the through holes 7 so that a second end face 5.1 of the cylindrical pins 5 lies within the through hole 7. The remaining free volume in the through hole 7 is then filled with adhesive 9.

If the optical block 1.1 and the mounting plate 1.2 are aligned parallel to each other in the adjusted relative position, all cylindrical pins 5 are glued equally deep in the through holes 7. This does not change for relative positions which differ in the x-direction, in the y-direction, in the z-direction or around the z-direction. A tilt around the x-direction or around the y-direction is compensated for by placing the cylindrical pins 5, arranged more or less deep in the through holes 7, in contact with the optical block 1.1. Unlike many adhesive connections known from the prior art, tilting does not have to be compensated for by the amount of adhesive 9. An equal amount of adhesive at all points where the connection is formed has the advantage that the behavior of the adhesive 9, e.g. shrinkage during solidification, has a similar effect everywhere, thus fixing the adjusted relative position with high precision.

### LIST OF REFERENCE NUMERALS

1 optical module
1.1 optical block
1.2 mounting plate
1.2.1 first end face of the mounting plate
1.2.1.1 elevation
1.2.2 circumference of the mounting plate
1.2.2.1 stop pin
2 electronic module
2.1 carrier plate
2.1.1 mounting surface
2.1.2 dowel pin
2.1.3 screw connection
2.2 printed circuit board
2.3 needle carrier
2.3.1 contacting needle
3 clamping pin
4 bending structure
5 cylindrical pin
5.1 first end face of the cylindrical pin
5.2 second end face of the cylindrical pin
6 set screw
7 through hole
8 contact pressure unit
9 adhesive
Sₒₚₜ optical interface
Sₑₗₑ electrical interface
Eₒₚₜ optical interface plane (of the contacting module)
Eₑₗₑ electrical interface plane (of the contacting module)

1. A contacting module, comprising:
an optical module including an optical block made of glass, with optical signal lines in a form of waveguides, with a mirror arranged in front of each waveguide, and with an arrangement of optical interfaces (Sₒₚₜ) in an optical interface plane (Eₒₚₜ), and
an electronic module, containing a carrier plate, a printed circuit board and a needle carrier with an arrangement of contacting needles with needle tips, which form an arrangement of electrical interfaces (Sₑₗₑ) in an electrical interface plane (Eₑₗₑ),
wherein the optical module and the electronic module are arranged relative to one another in such a way that the arrangement of optical interfaces (Sₒₚₜ) and the arrangement of electrical interfaces (Sₑₗₑ) have a defined adjustment position relative to one another with respect to all six degrees of freedom of a Cartesian coordinate system, and
wherein the optical module also includes a mounting plate to which the optical block is cohesively connected, and the mounting plate is connected to the electronic module via a repeatedly detachable connection, said detachable connection ensuring repeated production of the adjustment position of the arrangement of the optical interfaces (Sₒₚₜ) with respect to the arrangement of the electrical interfaces (Sₑₗₑ).

2. The contacting module according to claim 1, wherein, on a first end face of the mounting plate, three elevations defining a mounting plane are present, which rest against a mounting surface of the carrier plate, fixing a relative position of the mounting plate in a z-direction, about an x-direction and about a y-direction of a Cartesian coordinate system with respect to the carrier plate, and there are three stop pins on a circumferential surface of the mounting plate, which are aligned parallel to the mounting plane and are each contacted by a respective dowel pin provided on the carrier plate, thus fixing the relative position of the mounting plate in the x-direction, in the y-direction and around the z-direction to the carrier plate.

3. The contacting module according to claim 2, wherein two of the three dowel pins are arranged on an imaginary straight line oriented in the x-direction, two of the stop pins are aligned with each other in the x-direction, a third of the stop pins is aligned in the y-direction and the mounting plate is connected to the carrier plate via at least one screw connection.

4. The contacting module according to claim 1, wherein, on a first end face of the mounting plate, three elevations defining a mounting plane are present, which rest against a mounting surface of the carrier plate, whereby a relative position of the mounting plate in a z-direction, and about an x-direction and a y-direction of the Cartesian coordinate system with respect to the carrier plate is fixed, and the mounting plate has two bending structures penetrating the mounting plate, wherein in a first of the two bending structures, a first clamping pin attached to the carrier plate is clamped circumferentially via its lateral surface, thus fixing the relative position of the mounting plate in the x-direction and the y-direction to the carrier plate-, and in the second of the bending structures, a second clamping pin attached to the carrier plate is clamped tangentially via its lateral surface, thus fixing the relative position of the mounting plate around the z-direction to the carrier plate.

5. The contacting module according to claim 4, wherein the first bending structure has the shape of a pipe clamp, in which the first clamping pin is clamped in a self-centered manner.

6. The contacting module according to claim 1, wherein the optical block is permanently connected to the mounting plate via at least three cylindrical pins, wherein the cylindrical pins each contact the optical block with a first end face via adhesive, and in the mounting plate, there are through holes, in which the cylindrical pins are each connected indirectly to the mounting plate via adhesive.

7. A method for mounting a contacting module with an optical module, containing an optical block made of glass, which has an arrangement of optical interfaces (Sₒₚₜ) in an optical interface plane (Eₒₚₜ) and is mounted on a mounting plate, and an electronic module, containing a carrier plate, a printed circuit board and an arrangement of contacting needles with needle tips, which form an arrangement of electrical interfaces (Sₑₗₑ) in an electrical interface plane (Eₑₗₑ), the optical module and the electronic module being arranged relative to one another in such a way that the arrangement of optical interfaces (Sₒₚₜ) and the arrangement of electrical interfaces (Sₑₗₑ) have a defined adjustment position relative to one another, comprising:
before the optical block is fastened to the mounting plate, connecting the mounting plate to the carrier plate by means of a detachable connection in a relative position which can be produced repeatedly,
after connecting the mounting plate, adjusting the optical block relative to the mounting plate until the arrangement of the optical interfaces (Sₒₚₜ) has assumed a predetermined adjustment position relative to the arrangement of the electrical interfaces (Sₑₗₑ), and
finally, permanently connecting the optical block the mounting plate, whereby after each re-establishment of the detachable connection the arrangement of the optical interfaces (Sₒₚₜ) is arranged in the predetermined adjustment position relative to the arrangement of the electrical interfaces (Sₑₗₑ).

8. The method according to claim 7, wherein permanently connecting the optical block to the mounting plate includes making at least three through holes in the mounting plate parallel to each other, guiding at least three cylindrical pins through the through holes from a first end face of the mounting plate facing away from the optical block, until the at least three cylindrical pins each come into contact with the optical block, adhesive having previously been applied to a first end face of the cylindrical pins which faces the optical block, such that the cylindrical pins are glued in the through holes either during guiding or as a final step.
